(19) United States
(12) Patent Application Publication
(10) Pub. No.: US 2026/0240042 A1
(43) Pub. Date: Aug. 13, 2026

(54) SEMICONDUCTOR DEVICE AND MANUFACTURING METHOD THEREOF

(71) Applicant: Kioxia Corporation, Tokyo (JP)

(72) Inventors: Hiroki KITAYAMA, Yokkaichi (JP); Toshiyuki MORITA, Yokkaichi (JP)

(73) Assignee: Kioxia Corporation, Tokyo (JP)

(21) Appl. No.: 19/296,167

(22) Filed: Aug. 11, 2025

(30) Foreign Application Priority Data
Feb. 7, 2025 (JP) 2025-019377

(51) Int. Cl. H10W 90/00; H10B 80/00; H10W 72/00; H10W 72/90

(52) U.S. Cl. CPC H10W 90/00; H10B 80/00; H10W 72/01938; H10W 72/923; H10W 72/9415; H10W 72/952; H10W 90/792

(57) ABSTRACT

A semiconductor device according to the present embodiment includes first lines and second lines respectively located on a side of a first direction of an associated one of the first lines. First contacts electrically connect between an associated one of the first lines and an associated one of the second lines, respectively. Third lines respectively have a smaller width in a second direction intersecting with the first direction than those of the second lines and the first contacts and are respectively located on a side of the second direction of an associated one of the second lines. The first contacts are constituted of a first conductive material. The second and third lines are constituted of a second conductive material having a lower resistance than that of the first conductive material.

### CROSS REFERENCE TO RELATED APPLICATIONS

This application is based upon and claims the benefit of priority from the prior Japanese Patent Application No. 2025-019377, filed on February 7, 2025, the entire contents of which are incorporated herein by reference.

### FIELD

The embodiments of the present invention relate to a semiconductor device and a manufacturing method thereof.

### BACKGROUND

With downscaling of via contacts of a semiconductor device, the aspect ratio of the via contacts is increased. In a forming process of via contacts, the temperature in a film forming process is increasingly decreased to ensure a coverage of a conductor. In this case, there is a risk that lines having a narrow linewidth are filled with a conductor by low-temperature film formation similarly to the via contacts, and that the interconnection resistance is increased.

### BRIEF DESCRIPTION OF THE DRAWINGS

FIG. 1 is a sectional view illustrating a configuration example of a semiconductor device according to a first embodiment;

FIG. 2 is a schematic plan view illustrating a stacked body;

FIG. 3 is a schematic sectional view exemplifying memory cells of a three-dimensional structure;

FIG. 4 is another schematic sectional view exemplifying memory cells of a three-dimensional structure;

FIG. 5 is a sectional view illustrating a configuration example of an interconnection portion of an array chip according to the first embodiment;

FIG. 6 is a sectional view illustrating one example of a manufacturing method of the semiconductor device according to the first embodiment;

FIG. 7 is a sectional view illustrating one example of the manufacturing method of the semiconductor device according to the first embodiment in continuation from FIG. 6;

FIG. 8 is a sectional view illustrating one example of the manufacturing method of the semiconductor device according to the first embodiment in continuation from FIG. 7;

FIG. 9 is a sectional view illustrating one example of the manufacturing method of the semiconductor device according to the first embodiment in continuation from FIG. 8;

FIG. 10 is a sectional view illustrating one example of the manufacturing method of the semiconductor device according to the first embodiment in continuation from FIG. 9;

FIG. 11 is a sectional view illustrating a configuration example of a semiconductor device according to a second embodiment;

FIG. 12 is a sectional view illustrating one example of a manufacturing method of the semiconductor device according to the second embodiment;

FIG. 13 is a sectional view illustrating a configuration example of a semiconductor device according to a third embodiment; and

FIG. 14 is a sectional view illustrating one example of a manufacturing method of the semiconductor device according to the third embodiment.

### DETAILED DESCRIPTION

In general, according to the embodiment, a semiconductor device according to the present embodiment includes first lines and second lines respectively located on a side of a first direction of an associated one of the first lines. First contacts electrically connect between an associated one of the first lines and an associated one of the second lines, respectively. Third lines respectively have a smaller width in a second direction intersecting with the first direction than those of the second lines and the first contacts and are respectively located on a side of the second direction of an associated one of the second lines. The first contacts are constituted of a first conductive material. The second and third lines are constituted of a second conductive material having a lower resistance than that of the first conductive material. Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### First embodiment

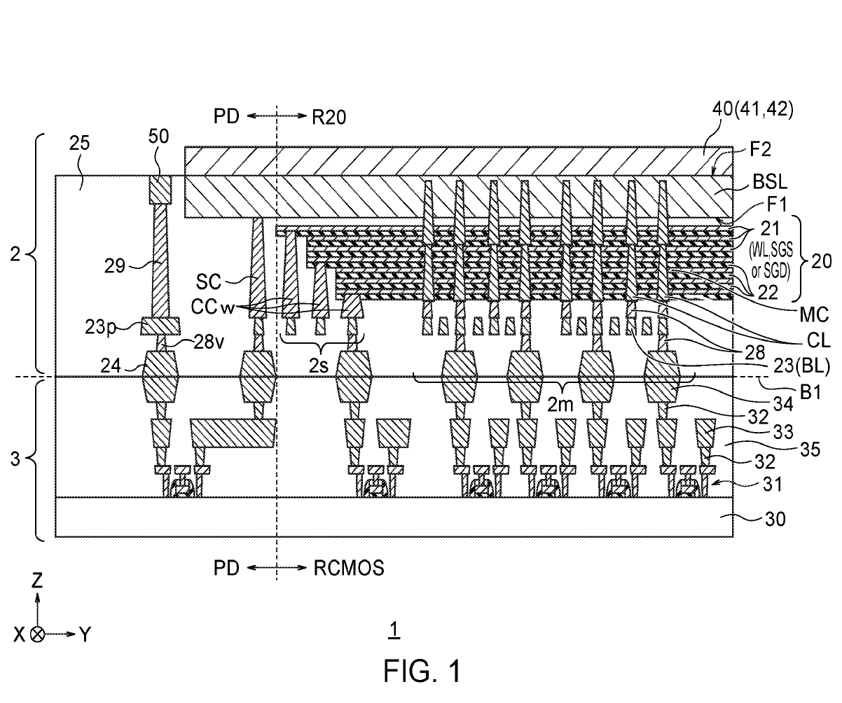

FIG. 1 is a sectional view illustrating a configuration example of a semiconductor device according to a first embodiment. In the present embodiment, a semiconductor device 1 is a NAND flash memory, for example. However, the present embodiment is not limited to a NAND flash memory and is applicable to other memories and semiconductor devices.

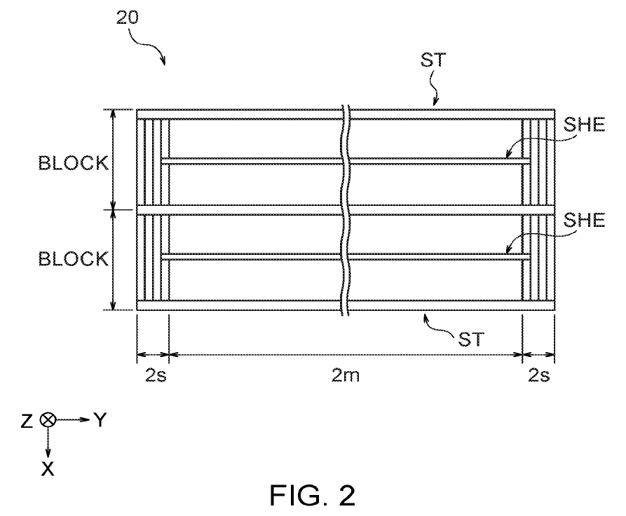

In the following descriptions, the stacking direction of a stacked body 20 is assumed as a Z direction. One direction intersecting with, for example, orthogonal to the Z direction is assumed as a Y direction. One direction intersecting with, for example, orthogonal to the Z direction and the Y direction is assumed as an X direction. In the present specification, the Z direction is one example of a first direction. The X direction is an example of a third direction and the Y direction is an example of a second direction. While the +Z direction is an upward direction in the descriptions of FIG. 1, the -Z direction is an upward direction in descriptions of FIG. 2 and subsequent drawings.

The semiconductor device 1 includes an array chip 2 having a memory cell array, and a CMOS (Complementary Metal Oxide Semiconductor) chip 3 having a CMOS circuit. The array chip 2 and the CMOS chip 3 are bonded to each other on a bonding face B1 and are electrically connected to each other with lines joined on the bonding face. FIG. 1 illustrates a state where the array chip 2 is located on the CMOS chip 3.

The CMOS chip 3 includes a substrate 30, transistors 31, vias 32, lines 33 and 34, and an interlayer dielectric film 35. RCMOS denotes a region in which CMOSs are located. PD denotes a region peripheral thereto.

The substrate 30 is, for example, a semiconductor substrate such as a silicon substrate. The transistors 31 are NMOS or PMOS transistors provided on the substrate 30. For example, transistors 31 constitute a CMOS circuit that controls the memory cell array of the array chip 2. A plurality of transistors 31 constitute a logic circuit such as a sense amplifier, a row decoder, or a column decoder. Semiconductor elements such as a resistive element and a capacitive element other than the transistors 31 may be formed on the substrate 30.

Each of the vias 32 electrically connects between a transistor 31 and a line 33 or between a line 33 and a line 34. The lines 33 and 34 constitute a multilayer interconnection structure in the interlayer dielectric film 35. The lines 34 are embedded in the interlayer dielectric film 35 and are exposed on the surface of the interlayer dielectric film 35 to be substantially flush with the surface. The lines 33 and 34 are electrically connected to the transistors 31 and the like. For example, a metal such as copper or tungsten is used as the vias 32, and the lines 33 and 34. The interlayer dielectric film 35 coats and protects the transistors 31, the vias 32, and the lines 33 and 34. For example, an insulating film such as a silicon dioxide film is used as the interlayer dielectric film 35.

The array chip 2 includes the stacked body 20, columnar bodies CL, slits ST (LI), a source layer BSL, a metallic layer 40, contact plugs CCw, contacts 29, lines 50, and an interlayer dielectric film 25. R20 denotes a region in which the stacked body 20 is located. PD denotes a region peripheral thereto.

The stacked body 20 is provided above the transistors 31 and is positioned in the Z direction with respect to the substrate 30. The stacked body 20 is configured by alternately stacking a plurality of electrode films 21 and a plurality of insulating films 22 along the Z direction. The stacked body 20 constitutes the memory cell array. For example, a conductive metal such as tungsten is used as the electrode films 21. As the insulating films 22, insulating films such as silicon dioxide films are used, for example. The insulating films 22 insulate the electrode films 21 from each other. That is, the electrode films 21 are stacked in a mutually insulated state. The numbers of stacked layers of the electrode films 21 and the insulating films 22 can be freely selected. The insulating films 22 may be, for example, porous insulating films or air gaps.

One electrode film 21 or plural electrode films 21 at the upper end and the lower end of the stacked body 20 in the Z direction function as source-side selection gates SGS and drain-side selection gates SGD, respectively. Electrode films 21 between the source-side selection gates SGS and the drain-side selection gates SGD function as word lines WL. The word lines WL are gate electrodes of memory cells MC. The source-side selection gates SGS are gate electrodes of source-side selection transistors. The drain-side selection gates SGD are gate electrodes of drain-side selection transistors. The source-side selection gates SGS are provided in an upper region of the stacked body 20. The drain-side selection gates SGD are provided in a lower region of the stacked body 20. The upper region represents a region of the stacked body 20 on a side far from the CMOS chip 3 (a side close to the metallic layer 40), and the lower region represents a region of the stacked body 20 on a side close to the CMOS chip 3.

The semiconductor device 1 includes a plurality of memory cells MC connected in series between each of the source-side selection transistors and an associated drain-side selection transistor. A structure in which a source-side selection transistor, memory cells MC, and a drain-side selection transistor are connected in series is referred to as "memory string" or "NAND string". A memory string is, for example, connected to a bit line BL through a via contact 28. The bit lines BL are the lines 23 provided below the stacked body 20 and extending in the X direction (the front-back direction of the drawing in FIG. 1). Therefore, in the following descriptions, the bit lines BL are also referred to as "bit lines 23".

A plurality of columnar bodies CL are provided in the stacked body 20. The columnar bodies CL extend in the stacked body 20 to penetrate through the stacked body 20 in the stacking direction (the Z direction) of the stacked body and are each located from a via contact 28 connected to an associated bit line 23 to the source layer BSL. An internal structure of the columnar bodies CL will be described later. In the present embodiment, each of the columnar bodies CL is formed in two tiers in the Z direction. However, there is no problem with the columnar bodies CL each formed in one tier. Alternatively, each of the columnar bodies CL may be formed in three or more tiers.

Although not illustrated in FIG. 1, a plurality of slits ST (see FIG. 2) are provided in the stacked body 20. The slits ST extend in the Y direction and penetrate through the stacked body 20 in the stacking direction (the Z direction) of the stacked body 20. An insulating film such as a silicon dioxide film is filled in each of the slits ST and the insulating film is configured in a plate shape. The slits ST electrically separate the electrode films 21 of the stacked body 20 from each other. It is alternatively possible that the inner wall of each of the slits ST is coated with an insulating film such as a silicon dioxide film and that a conductive material is further embedded in the inner side of the insulating film. In this case, the conductive material can also function as a source line reaching the source layer BSL.

The source layer BSL is located on the stacked body 20. The source layer BSL is provided corresponding to the stacked body 20. The source layer BSL has a first face F1 and a second face F2 on the opposite side to the first face F1. The stacked body 20 (memory cell array) is located on the side of the face F1 of the source layer BSL, and the metallic layer 40 is located on the side of the face F2. The metallic layer 40 includes a source line 41 and a power line 42. The source layer BSL is connected in common to one ends of the columnar bodies CL and provides the columnar bodies CL in the same memory cell array 2m with a common source potential. That is, the source layer BSL functions as a common source electrode of the memory cell array 2m. For example, a conductive material such as doped polysilicon is used as the source layer BSL. For example, a metallic material such as copper, aluminum, or tungsten having a lower resistance than that of the source layer BSL is used as the metallic layer 40. In FIG. 1, 2s denotes a stepped portion of the electrode films 21 provided to connect the electrode films 21 to associated contact plugs CCw. The stepped portion 2s will be described later with reference to FIG. 2.

The contact plugs CCw are provided at ends of the stacked body 20 and extend in the Z direction in the interlayer dielectric film 25. Each of the contact plugs CCw is electrically connected between an electrode film 21 (a word line WL) and a line 24. The contact plugs CCw are located at the stepped portions 2s formed in the manner of stairs at ends of the stacked body 20 and are each electrically connected to an associated electrode film 21. The contact plugs CCw are provided to transmit a word line voltage from the CMOS chip 3 to the associated electrode films 21. For example, a metal such as tungsten is used as the contact plugs CCw.

The via contacts 28, the lines 23, and the lines 24 are provided below (in the -Z direction of) the stacked body 20. The lines 23 and 24 are embedded in the interlayer dielectric film 25. The lines 24 are exposed on the surface of the interlayer dielectric film 25 to be substantially flush with the surface. The lines 23 and 24 are electrically connected to semiconductor bodies 210 of the columnar bodies CL, or the like. For example, a metal such as tungsten is used as the via contacts 28, the lines 23, and the lines 24. The interlayer dielectric film 25 coats and protects the stacked body 20, the via contacts 28, the lines 23, and the lines 24. For example, an insulating film such as a silicon dioxide film is used as the interlayer dielectric film 25.

Meanwhile, the lines 50 are located in the peripheral region PD to the stacked body 20. For example, the lines 50 may be connected to bonding pads (not illustrated) or the like that receive power supply or signals from outside the semiconductor device 1. The lines 50 are each provided to be connected to one end of a contact 29 in the Z direction. The lines 50 are each connected to a transistor 31 of the CMOS chip 3 via the associated contact 29, an associated line 24, and an associated line 34. Accordingly, for example, external power supplied from a line 50 is supplied to the associated transistor 31. Alternatively, a signal is supplied to a transistor 31 or the memory cell array 2m via the associated line 50.

The contacts 29 are located in the peripheral region PD to the stacked body 20 and extend in the Z direction in the interlayer dielectric film 25. The contacts 29 are contacts each provided between a line 24 and an associated line 50. The contacts 29 are simultaneously formed in the same process as that of the contact plugs CCw connected to the word lines WL.

The contacts 29 are each connected between a line 50 and a line 23p. The contacts 29 have, for example, a substantially circular, substantially rectangular, or substantially elliptical shape in an X-Y plane and do not extend in the X direction or the Y direction. Each of the contacts 29 may be used, for example, to supply a power voltage or a signal from the associated line 50 to the array chip 2 or the CMOS chip 3. For example, a metal such as copper or tungsten is used as the contacts 29. The power voltage is, for example, a power voltage VDD, or a reference voltage (for example, a ground voltage) VSS lower than the power voltage VDD. The signal may be a control signal from outside, or may be data to be written or read data.

The lines 23p are located in the peripheral region PD. The lines 23p are each connected between a contact 29 and a via contact 28v. The lines 23p extend in the interlayer dielectric film 25 in the X direction or the Y direction. In FIG. 1, the lines 23p extend in the X direction. The lines 23p are in the same layer as that of the bit lines 23 and are formed simultaneously in the same process. However, the lines 23p function as interconnections in the peripheral region PD unlike the bit lines 23. The same conductive material (for example, tungsten) as that of the bit lines 23 is used as the lines 23p.

The via contacts 28v are located in the peripheral region PD. The via contacts 28v are each connected between a line 23p and an associated line 24. The via contacts 28v have, for example, a substantially circular, substantially rectangular, or substantially elliptical shape in the X-Y plane and do not extend in the X direction or the Y direction. The via contacts 28v are in the same layer as that of the via contacts 28 and are formed simultaneously in the same process. The same conductive material (for example, tungsten) as that of the via contacts 28 is used as the via contacts 28v.

In the present embodiment, the array chip 2 and the CMOS chip 3 are individually formed and are bonded to each other on the boding face B1. Therefore, the transistors 31 are not provided in the array chip 2. The stacked body 20 (memory cell array) is not provided in the CMOS chip 3. The transistors 31 and the stacked body 20 are both on the side of the first face F1 of the source layer BSL. The transistors 31 are on the opposite side to the second face F2 where the metallic layer 40 is located.

The interlayer dielectric film 25 and the interlayer dielectric film 35 are bonded to each other on the bonding face B1. Associated therewith, the lines 24 and the lines 34 are joined to each other on the bonding face B1 to be substantially flush therewith. Accordingly, the array chip 2 and the CMOS chip 3 are electrically connected to each other via the lines 24 and the lines 34.

FIG. 2 is a schematic plan view illustrating the stacked body 20. The stacked body 20 includes the stepped portions 2s and the memory cell array 2m. The stepped portions 2s are located at ends of the stacked body 20, for example. The memory cell array 2m is sandwiched or surrounded by the stepped portions 2s. The slits ST (LI) are provided from the stepped portion 2s at one end of the stacked body 20 through the memory cell array 2m to the stepped portion 2s at the other end of the stacked body 20. Slits SHE are provided at least on the memory cell array 2m. The slits SHE are shallower in the Z direction than the slits ST (LI) and extend substantially in parallel to the slits ST (LI). The slits SHE electrically separate the electrode films 21 for each of the drain-side selection gates SGD. The slits ST may be source lines LI electrically connected to the source layer BSL while electrically isolated from the electrode films 21 of the stacked body 20. That is, the slits ST may be source lines LI electrically isolated from the electrode films 21 of the stacked body 20 constituting the memory cell array and electrically connected to the source layer BSL.

A portion of the stacked body 20 sandwiched by two slits ST illustrated in FIG. 2 is referred to as "block (BLOCK)". A block constitutes, for example, a minimum unit of data erasing. A slit SHE is provided in each block. The stacked body 20 between a slit ST and a slit SHE is referred to as "finger". The drain-side selection gates SGD are divided for each finger. Accordingly, at the time of writing and reading data, one finger in a block can be brought to a selected state by the associated drain-side selection gate SGD.

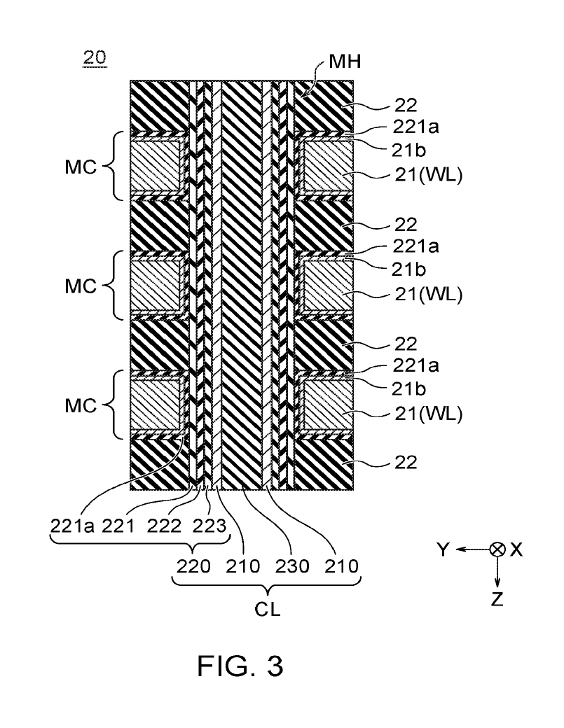

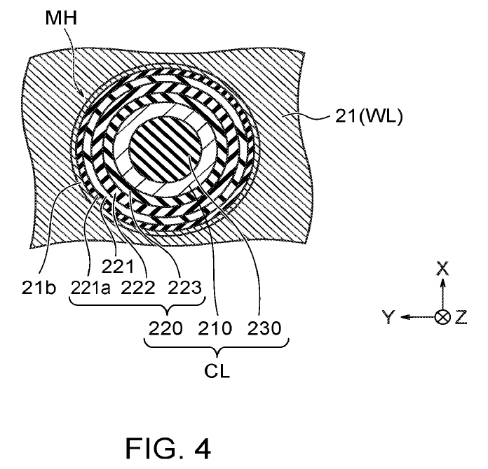

FIGS. 3 and 4 are schematic sectional views exemplifying memory cells of a three-dimensional structure. The columnar bodies CL are each provided in a memory hole MH formed in the stacked body 20. Each of the columnar bodies CL penetrates through the stacked body 20 along the Z direction from one end part of the stacked body 20 to be provided in the stacked body 20 and the source layer BSL. Each of the columnar bodies CL includes the semiconductor body 210, a memory film 220, and a core layer 230. Each columnar body CL includes the core layer 230 located at a central part thereof, the semiconductor body (a semiconductor member) 210 located around the core layer 230, and the memory film 220 located around the semiconductor body 210. The semiconductor body 210 extends in the stacked body 20 in the stacking direction (the Z direction). The semiconductor body 210 is electrically connected to the source layer BSL. The memory film 220 is located between the semiconductor body 210 and the electrode films 21 and has charge capturing parts. A plurality of the columnar bodies CL each selected from each finger are connected in common to one bit line 23 through the via contacts 28 in FIG. 1. Each of the columnar bodies CL is provided, for example, in a region of the memory cell array 2m.

As illustrated in FIG. 3, the shape of each of the memory holes MH in the X-Y plane is circular or elliptic, for example. A block dielectric film 221a constituting a part of the memory film 220 may be provided between each of the electrode films 21 and adjacent insulating films 22. The block dielectric film 221a is a silicon oxide or a metal oxide, for example. One example of the metal oxide is an aluminum oxide. As illustrated in FIG. 4, a barrier film 21b may be provided between each of the electrode films 21 and adjacent insulating films 22 and between each of the electrode films 21 and the memory film 220. The barrier film 21b is, for example, a laminated film including titanium nitride and titanium, for example, when the electrode films 21 are tungsten. The block dielectric film 221a suppresses back tunneling of charges from the electrode films 21 to the memory film 220. The barrier film 21b enhances adhesion between the electrode films 21 and the block dielectric film 221a.

The shape of the semiconductor body 210 is a bottomed tube, for example. For example, polysilicon is used as the semiconductor body 210. The semiconductor body 210 is undoped silicon, for example. Alternatively, the semiconductor body 210 may be p-type silicon. The semiconductor body 210 functions as channels of the drain-side selection transistors, the memory cells MC, and the source-side selection transistors. That is, a plurality of the memory cells MC each have a storage region between the semiconductor body 210 and an electrode film 21 functioning as a word line WL and are stacked in the Z direction. One ends of a plurality of the semiconductor bodies 210 in the same memory cell array 2m are electrically connected in common to the source layer BSL.

The memory film 220 includes, for example, a cover dielectric film 221, a charge capturing film 222, a tunnel dielectric film 223, and the block dielectric film 221a. A portion of the memory film 220 other than the block dielectric film 221a is located between the inner wall of the memory hole MH and the semiconductor body 210. The shape of the memory film 220 is tubular, for example. Each of the charge capturing film 222 and the tunnel dielectric film 223 extends in the Z direction.

The cover dielectric film 221 is located between the insulating films 22 and the charge capturing film 222 and between the block dielectric film 221a and the charge capturing film 222. The cover dielectric film 221 includes a silicon oxide, for example. The cover dielectric film 221 protects the charge capturing film 222 from being etched when sacrificial films (not illustrated) are replaced by the electrode films 21 (in a replacing process). In a case where the replacing process is not used to form the electrode films 21, it is possible that the cover dielectric film 221 is not provided.

The charge capturing film 222 is located between the cover dielectric film 221 and the tunnel dielectric film 223. The charge capturing film 222 includes, for example, a silicon nitride and has a trap site that traps charges in the film. Portions of the charge capturing film 222 sandwiched between the electrode films 21 functioning as the word lines WL and the semiconductor body 210 constitute the storage regions of the memory cells MC as the charge capturing parts. The threshold voltage of each of the memory cells MC varies according to whether there are charges in the associated charge capturing part or the quantity of charges captured in the charge capturing part. Accordingly, each of the memory cells MC retains information.

The tunnel dielectric film 223 is located between the semiconductor body 210 and the charge capturing film 222. The tunnel dielectric film 223 includes, for example, a silicon oxide, or a silicon oxide and a silicon nitride. The tunnel dielectric film 223 is a potential barrier between the semiconductor body 210 and the charge capturing film 222. For example, when electrons are injected from the semiconductor body 210 to the charge capturing film 222 (a write operation) and when positive holes are injected from the semiconductor body 210 to the charge capturing film 222 (an erase operation), the electrons and the positive holes each pass through (tunnel) the potential barrier of the tunnel dielectric film 223.

The core layer 230 fills the internal space of the tubular semiconductor body 210. The shape of the core layer 230 is columnar, for example. The core layer 230 includes a silicon oxide, for example, and is insulating.

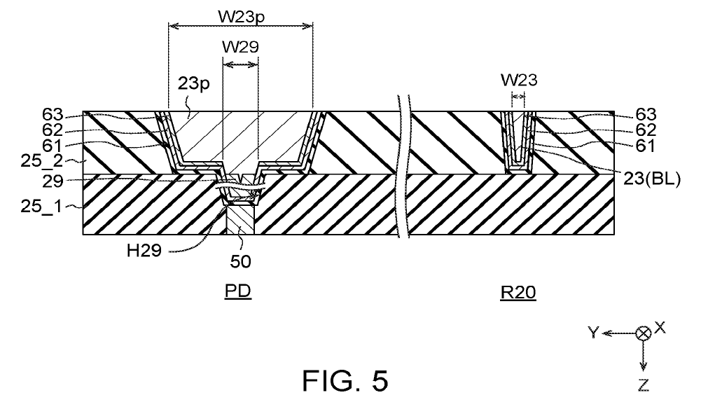

FIG. 5 is a sectional view illustrating a configuration example of an interconnection portion of the array chip according to the first embodiment. FIG. 5 illustrates a configuration example of the region R20 where the stacked body 20 is located, and the peripheral region PD thereto. The following descriptions are made assuming the -Z direction as upward.

The semiconductor device 1 according to the present embodiment includes interlayer dielectric films 25_1 and 25_2. The lines 50, the contacts 29, the lines 23p, a barrier metal layer 61, a nucleation film 62, and a conductive film 63 are provided in the peripheral region PD of the semiconductor device 1. The bit lines 23, the barrier metal layer 61, the nucleation film 62, the conductive film 63 are provided in the region R20 where the stacked body 20 of the semiconductor device 1 is located. The boundary or thickness of each of the barrier metal layer 61, the nucleation film 62, and the conductive film 63 is sometimes unclear. Therefore, the barrier metal layer 61, the nucleation film 62, and the conductive film 63 can be referred to also as the barrier metal region 61, the nucleation region 62, and the conductive region 63, respectively. The thickness of each of the barrier metal layer 61, the nucleation film 62, and the conductive film 63 can be within a predetermined range from the peak of the concentration of components included therein as the center.

The interlayer dielectric films 25_1 and 25_2 are parts of the interlayer dielectric film 25 in FIG. 1 and are located on the stacked body 20. The interlayer dielectric film 25_1 is an insulating film in which the lines 50 and the contacts 29 are located. The interlayer dielectric film 25_2 is an insulating film in which the lines 23p and the bit lines 23 are located.

The lines 50 being first lines are located in the interlayer dielectric film 25_1. For example, a conductive material such as tungsten, copper, or doped silicon is used as the lines 50.

The lines 23p being second lines are located in the interlayer dielectric film 25_2. Each of the lines 23p is located above (in the -Z direction of) an associated line 50 and is electrically connected to the line 50 via an associated contact 29. For example, a second conductive material such as tungsten is used as the lines 23p.

Each of the contacts 29 being first contacts is located between an associated line 50 and an associated line 23p, and electrically connect the line 50 and the line 23p to each other. Each of the contacts 29 is located in an associated one of contact holes H29 provided in the interlayer dielectric film 25_1. While a part of illustrations is omitted in FIG. 5, the contacts 29 extend deeply downward (in the +Z direction) in the interlayer dielectric film 25_1. For example, a first conductive material such as tungsten is used as the contacts 29.

The bit lines 23 being third lines are provided in the region R20 where the stacked body 20 is located. The bit lines 23 are located in the same layer as the lines 23p and arranged in the -Y direction of the lines 23p. The bit lines 23 are provided to extend in the X direction in the interlayer dielectric film 25_2. The same material as that of the lines 23p is used as the bit lines 23 and the second conductive material such as tungsten is used, for example.

The barrier metal layer 61 is located between each of the contacts 29 and the interlayer dielectric film 25_1 and between each of the lines 23p and the interlayer dielectric films 25_1 and 25_2 in the peripheral region PD. In the region R20, the barrier metal layer 61 is located between each of the bit lines 23 and the interlayer dielectric films 25_1 and 25_2. The barrier metal layer 61 is provided to prevent the materials (for example, tungsten) of the contacts 29, the lines 23p, and the bit lines 23, and by-products thereof from diffusing. For example, Ti or TiN, or a laminated film including Ti and TiN is used as the barrier metal layer 61.

The nucleation film 62 being a first conductive film is provided between each of the contacts 29 and the associated line 50. The nucleation film 62 is provided also on the side surface of each of the contacts 29. Furthermore, the nucleation film 62 is provided on the side surface of each of the lines 23p and the side surface of each of the bit lines 23, with the conductive film 63 interposed therebetween.

The nucleation film 62 has a function to promote film formation of a conductive material (for example, tungsten). For example, a tungsten film including boron, or a tungsten film including silicon is used as the nucleation film 62.

The conductive film 63 being a second conductive film is provided between each of the lines 23p and the nucleation film 62 and between each of the bit lines 23 and the nucleation film 62 while not being provided between each of the contacts 29 and the nucleation film 62. That is, the conductive film 63 is not provided in the contact holes H29. For example, a conductive material such as tungsten (WN) including nitrogen is used as the conductive film 63. The concentration of nitrogen included in the conductive film 63 is higher than the concentration of nitrogen included in the nucleation film 62. Tungsten having a high nitrogen concentration is unlikely to cause tungsten to be deposited thereon. The conductive film 63 may be tungsten including boron in addition to nitrogen.

The first conductive material constituting the contacts 29 is, for example, tungsten formed at a low temperature equal to or lower than 350°C. While hardly being deposited on the conductive film 63 (for example, tungsten (WN) including nitrogen), such tungsten formed at a low temperature can be deposited on the nucleation film 62 (for example, tungsten having a low nitrogen concentration). On the other hand, tungsten formed at a temperature equal to or higher than 350°C is likely to cause a material gas (WF₆) to reduce and is likely to be deposited. Therefore, tungsten formed at a high temperature can be deposited also on the conductive film 63. As described above, the conductive film 63 is a material that is less likely to cause tungsten to be deposited than the nucleation film 62. Therefore, with an appropriate formation temperature of the first conductive material (for example, tungsten), the first conductive material can be selectively deposited on the nucleation film 62 without deposition of the first conductive material on the conductive film 63.

The following descriptions are made assuming that the first conductive material is tungsten formed at a low temperature as one example.

In each of the contact holes H29, the conductive material (for example, tungsten) of the contacts 29 is provided on the nucleation film 62. The conductive film 63 is not provided in the contact holes H29. The first conductive material of the contacts 29 is, for example, tungsten formed at a low temperature equal to or lower than 350°C. In the case of tungsten formed at a low temperature, reduction of the material gas (for example, WF₆) requires time. That is, the incubation time becomes longer. Therefore, the material gas (for example, WF₆) can reach the bottom part of each of the contact holes H29 before being reduced. Accordingly, tungsten of the contacts 29 has a high level of coverage and can be deposited also on the bottom part of each of the contact holes H29. Further, the conductive film 63 is not provided in the contact holes H29 and the nucleation film 62 that promotes film formation of tungsten is exposed. Therefore, tungsten can be filled in the contact holes H29 having a high aspect ratio.

Meanwhile, as described above, tungsten formed at a low temperature takes a long time to incubate and is not formed on the conductive film 63. Therefore, the lines 23p and the bit lines 23 are not formed of the same tungsten as that of the contacts 29. Further, tungsten formed at a low temperature has a relatively high concentration of impurities (for example, fluorine) and is high in the resistance. Accordingly, if the lines 23p and the bit lines 23 are formed of the same tungsten formed at a low temperature as that of the contacts 29, the interconnection resistances of the lines 23p and the bit lines 23 unfavorably become high.

In the present embodiment, the lines 23p and the bit lines 23 are filled with, for example, tungsten formed at a high temperature equal to or higher than 350°C. In the case of tungsten formed at a high temperature, the material gas (for example, WF₆) is easily reduced and the incubation time is short. Therefore, such tungsten formed at a high temperature has a low level of coverage and has difficulty filling the contacts 29 while it is easily deposited also on the conductive film 63 and can fill the lines 23p and the bit lines 23.

Furthermore, since being lower in the concentration of impurities (for example, fluorine) and has a larger particle diameter than tungsten formed at a low temperature, tungsten formed at a high temperature has a low resistance. Therefore, the lines 23p and the bit lines 23 can be decreased in the resistance by being filled with tungsten formed at a high temperature. That is, the lines 23p and the bit lines 23 can be filled with the second conductive material lower in the resistance than the first conductive material of the contacts 29. The second conductive material of the lines 23p and the bit lines 23 is, for example, tungsten similarly to the first conductive material of the contacts 29. However, for example, the second conductive material is tungsten formed at a high temperature equal to or higher than 350°C, which is lower in the concentration of impurities (for example, fluorine) and is lower in the resistance than tungsten of the first conductive material. Therefore, it can be said that tungsten formed at a high temperature equal to or higher than 350°C is suitable for the second conductive material of the lines 23p and the bit lines 23.

The following descriptions are made assuming that the second conductive material of the lines 23p and the bit lines 23 is tungsten formed at a high temperature as an example.

For example, with downscaling of the memory cell array 2m, the linewidth and the interval (the line and space) of the bit lines 23 are also narrowed. Therefore, a width W23 of each of the bit lines 23 in the Y direction is significantly narrower than a width W29 of each of the contacts 29 and a width W23p of each of the lines 23p in the Y direction (W23<W29<W23p). Furthermore, with increase in the memory capacity, the length of each of the bit lines 23 becomes longer. Accordingly, the interconnection resistance of the bit lines 23 tends to be increased. Under such circumstances, it is unfavorable to form the bit lines 23 of high-resistance tungsten formed at a low temperature. However, it can be said that it is preferable to form the lines 23p and the bit lines 23 of low-resistance tungsten formed at a high temperature. It is particularly advantageous that the increasingly downscaled bit lines 23 are formed of low-resistance tungsten.

As described above, in the present embodiment, the contacts 29 are filled with, for example, high-coverage tungsten formed at a low temperature, and the lines 23p and the bit lines 23 are filled with, for example, low-resistance tungsten formed at a high temperature. Accordingly, the contacts 29 can be filled with tungsten having a high level of coverage and the lines 23p and the bit lines 23 can be filled with low-resistance tungsten.

The second conductive material provided in each of the lines 23p and the bit lines 23 is lower in the impurity concentration (for example, the fluorine concentration) and has a larger particle diameter while being tungsten similarly to the first conductive material provided in each of the contacts 29. Therefore, the second conductive material formed at a high temperature is lower in the resistance than the first conductive material formed at a low temperature.

The first conductive material and the second conductive material are types of tungsten different in the impurity concentration and the particle diameter. Therefore, there is an interface between the first conductive material of the contacts 29 and the second conductive material of the lines 23p.

The barrier metal layer 61 and the nucleation film 62 are located between each of the lines 50 and the associated contact 29. Meanwhile, the barrier metal layer 61, the nucleation film 62, and the conductive film 63 are not interposed between each of the contacts 29 and the associated line 23p. That is, each of the contacts 29 is in direct contact with the associated line 23p. This is because formation of the lines 23p of the second conductive material follows formation of the contacts 29 of the first conductive material. That is, it is understood that the semiconductor device according to the present embodiment is formed using a dual-damascene method.

A manufacturing method of the semiconductor device 1 according to the present embodiment is described next.

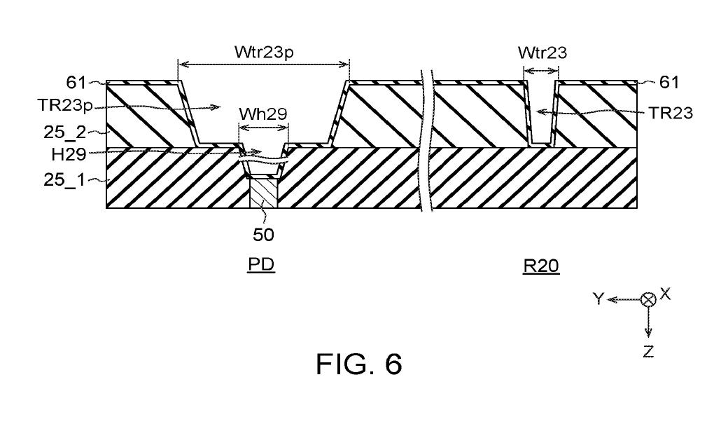

FIGS. 6 to 10 are sectional views illustrating one example of the manufacturing method of the semiconductor device according to the first embodiment.

First, the stacked body 20 is formed in the region R20 of a substrate (not illustrated) and the interlayer dielectric film 25_1 is formed on the substrate.

Next, the lines 50 are formed in the interlayer dielectric film 25_1 in the peripheral region PD. For example, a conductive material such as tungsten is used as the lines 50. As the interlayer dielectric film 25_1, an insulating material such as a silicon oxide is used, for example. While the lines 50 may be lines formed on the substrate, the lines 50 are not limited thereto and may be an impurity diffused layer formed on the substrate.

Next, the material of the interlayer dielectric film 25_1 is further deposited on the lines 50 and the interlayer dielectric film 25_2 is deposited on the interlayer dielectric film 25_1. For example, an insulating material such as silicon oxide is used as the interlayer dielectric film 25_2. Although not illustrated in the drawings, lines and via contacts (both not illustrated) to be connected to the stacked body 20 are formed also in the region R20.

Next, the contact holes H29 and trenches TR23p and TR23 are formed in the interlayer dielectric films 25_1 and 25_2 using a lithography technique and an etching technique. In the peripheral region PD, each of the contact holes H29 extends in the -Z direction in the interlayer dielectric film 25_1 and reaches the associated line 50. Each of the trenches TR23p is provided in the -Z direction of the associated contact hole H29 and is communicated with the contact hole H29. The trenches TR23p are provided in the interlayer dielectric film 25_2 and extend, for example, in the X direction. The trenches TR23p are used to form the lines 23p. In the region R20, the trenches TR23 are provided in the interlayer dielectric film 25_2 and extend, for example, in the X direction. Since each of the trenches TR23 is used for, for example, a bit line 23, each of the trenches TR23 reaches a via contact (not illustrated) connected to the semiconductor body 210 of the associated columnar body CL in the stacked body 20.

A width Wtr23p of each of the trenches TR23p in the Y direction is larger than a width Wh29 of each of the contact holes H29 in the Y direction. A width Wtr23 of each of the trenches TR23 in the Y direction is smaller than the width Wh29 of each of the contact holes H29 and the width Wtr23p of each of the trenches TR23p.

Next, the barrier metal layer 61 is formed on the inner wall of each of the trenches TR23p and TR23 and the contact holes H29 by a CVD (Chemical Vapor Deposition) method or the like as illustrated in FIG. 6. For example, Ti or TiN, or a laminated film including Ti and TiN is used as the barrier metal layer 61. The barrier metal layer 61 facilitates deposition of a metallic material such as tungsten.

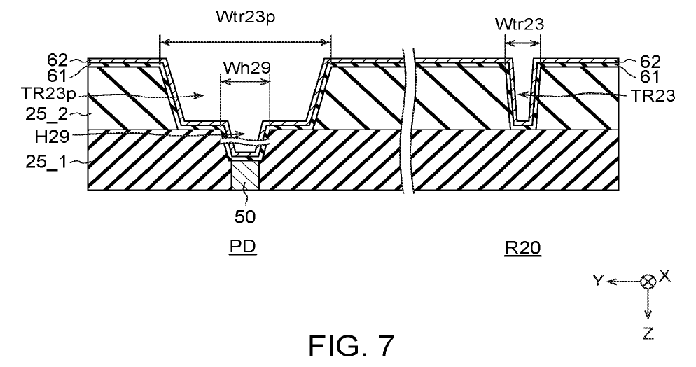

Next, the nucleation film 62 is formed in the trenches TR23p and TR23 and the contact holes H29 by a CVD method or the like as illustrated in FIG. 7. The nucleation film 62 is formed on the inner wall of each of the trenches TR23p and TR23 and the contact holes H29 with the barrier metal layer 61 interposed therebetween. The nucleation film 62 is, for example, tungsten formed of a material gas (tungsten fluoride: WF₆) with diborane (B₂H₆) or silane (SiH₄) added as a reducing gas. The resultant tungsten is tungsten including a large amount of boron or silicon and being relatively high in the resistance. However, the nucleation film 62 can promote deposition of the first conductive material (for example, tungsten) of the contacts 29 formed thereafter and can enhance adhesion of the first conductive material to the lines 50 or the interlayer dielectric film 25_1.

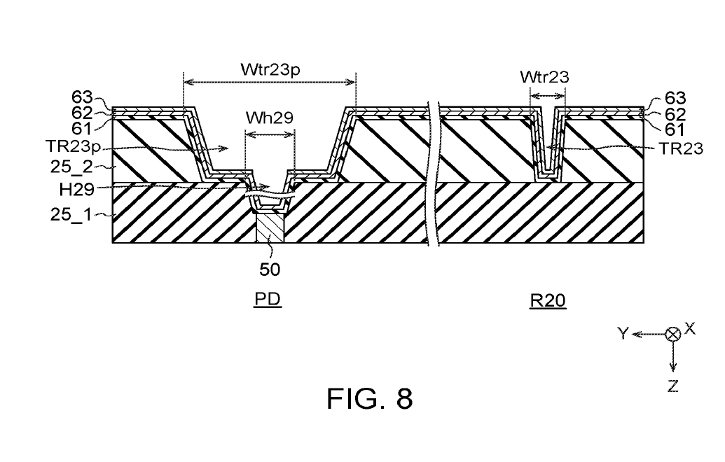

Next, the conductive film 63 is selectively formed on the nucleation film 62 in the trenches TR23p and TR23 by a CVD method or the like as illustrated in FIG. 8. The conductive film 63 is formed while the coverage is decreased by a plasma CVD method or the like or the supply rate control of the material gas is executed. Therefore, while being formed on the nucleation film 62 in the trenches TR23p and TR23, the conductive film 63 is hardly formed on the nucleation film 62 in the contact holes H29. The conductive film 63 is, for example, tungsten formed of a material gas (tungsten fluoride: WF₆) with ammonia (NH₃) added as a reducing gas. The resultant tungsten is tungsten (for example, tungsten nitride (WN)) including a large amount of nitrogen and being higher in the resistance than the nucleation film 62. Tungsten nitride is less likely to grow tungsten than tungsten boride or tungsten silicide. Accordingly, the conductive film 63 suppresses more the materials (for example, tungsten) of the contacts 29, the lines 23p, and the bit lines 23 from being deposited than the nucleation film 62. That is, the conductive film 63 functions as a formation suppressing film (a mask material) for the materials of the contacts 29, the lines 23p, and the bit lines 23. The conductive film 63 may be formed of the material gas (WF₆) with ammonia (NH₃) and diborane (B₂H₆) added as a reducing gas. In this case, the conductive film 63 becomes tungsten (WBN) including a large amount of nitrogen and boron and being relatively high in the resistance. While being tungsten (WBN), the conductive film 63 can maintain the function described above.

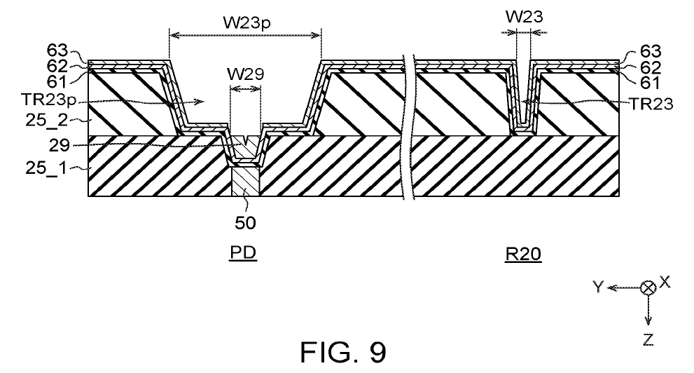

Next, for example, the conductive material (for example, tungsten) of the contacts 29 is formed at a low temperature equal to or lower than 350°C. In the case of a low temperature equal to or lower than 350°C, reduction of the material gas (for example, WF₆) takes time and the incubation time is long. Therefore, the material gas (for example, WF₆) can reach the bottom part of each of the contact holes H29 before being reduced. Accordingly, the conductive material of the contacts 29 has a high level of coverage and can be filled also in the bottom part of each of the contact holes H29 having a high aspect ratio as illustrated in FIG. 9. Therefore, the contacts 29 are formed of the first conductive material (for example, tungsten relatively high in the impurity concentration).

Meanwhile, although tungsten formed at a low temperature described above is deposited on the nucleation film 62 that promotes deposition, this tungsten is not deposited on the conductive film 63. Therefore, while the tungsten formed at a low temperature is selectively embedded in each of the contact holes H29, it is hardly formed in the trenches TR23p and TR23. While tungsten formed at a low temperature has a high level of coverage, this tungsten is relatively high in the concentration of impurities (for example, fluorine) and has a high resistance. Accordingly, it is preferable that this first conductive material is used only for formation of the contacts 29 having a high aspect ratio and is not used for formation of the lines 23p and the bit lines 23.

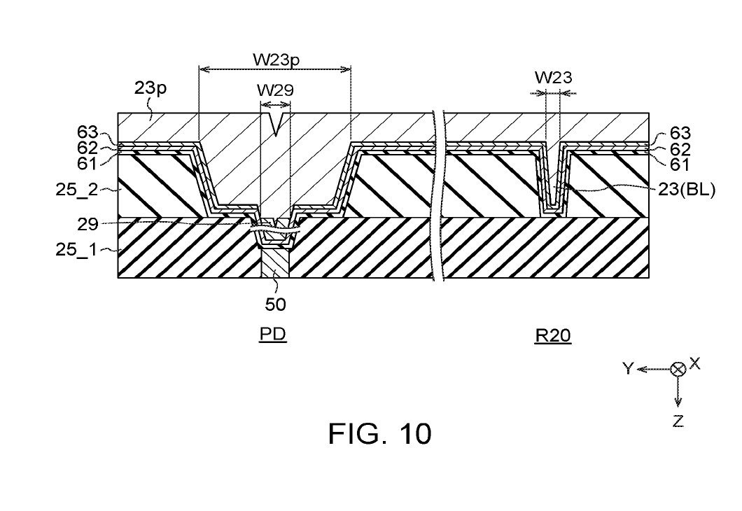

Next, for example, the conductive material (the second conductive material) (for example, tungsten) of the lines 23p and the bit lines 23 is formed at a high temperature equal to or higher than 350°C. In the case of a high temperature equal to or higher than 350°C, reduction of the material gas (for example, WF₆) is promoted and the incubation time is short. Therefore, the material gas (for example, WF₆) is reduced in a short time and causes tungsten to be deposited easily also on the conductive film 63. Accordingly, tungsten of the second conductive material is deposited in the trenches TR23p and TR23. This enables the trenches TR23p and TR23 to be filled with tungsten formed at a high temperature as illustrated in FIG. 10. Tungsten formed at a high temperature is lower in the impurity concentration than tungsten formed at a low temperature. Therefore, the lines 23p and the bit lines 23 are formed of the second conductive material (for example, tungsten relatively low in the fluorine concentration) that is lower in the impurity concentration than the first conductive material. Each of the lines 23p is formed above (in the -Z direction of) the associated contact 29 and is in direct contact with the contact 29. The bit lines 23 are formed in the -Y direction of the lines 23p and are electrically insulated from the contacts 29 and the lines 23p.

Tungsten formed at a high temperature described above is deposited also on the conductive film 63 that has a formation suppressing function for tungsten. Therefore, tungsten formed at a higher temperature than the formation temperature of the contacts 29 can be formed in the trenches TR23p and TR23. Furthermore, tungsten formed at a higher temperature than the formation temperature of the contacts 29 is relatively low in the concentration of impurities (for example, fluorine) and has a low resistance. Accordingly, with use of tungsten formed at a high temperature as the lines 23p and the bit lines 23, the interconnection resistances of the lines 23p and the bit lines 23 can be decreased.

Next, the lines 23p, the bit lines 23, the conductive film 63, the nucleation film 62, and the barrier metal layer 61 are polished by a CMP (Chemical Mechanical Polishing) method or the like until the interlayer dielectric film 25_2 is exposed. The structure illustrated in FIG. 5 is thereby obtained.

Subsequently, this structure is bonded with a CMOS wafer separately formed, the substrate on the back side (on the +Z side) of the stacked body 20 is removed, and the metallic layer 40 and the like are formed on the back side of the stacked body 20 as required. Further, the bonded wafer is singulated into chips in a dicing process. The semiconductor device 1 is thereby completed.

As described above, in the present embodiment, the contacts 29 are formed of, for example, tungsten formed at a low temperature and having a high level of coverage, and the lines 23p and the bit lines 23 are formed of, for example, tungsten formed at a high temperature and being low in the resistance. Accordingly, the contacts 29 can be formed of tungsten having a high level of coverage and the lines 23p and the bit lines 23 can be formed of low-resistance tungsten.

In the present embodiment, formation of the lines 23p of tungsten formed at a high temperature follows formation of the contacts 29 of tungsten formed at a low temperature. In this way, the dual-damascene method is used in the present embodiment. Therefore, each of the lines 50 is in direct contact with the associated contact 29 and the barrier metal layer 61, the nucleation film 62, and the conductive film 63 are not interposed therebetween.

While being provided on the side surface and a part of the bottom surface of each of the trenches TR23p and TR23, the conductive film 63 is not provided on the side surface and the bottom surface of each of the contact holes H29. The conductive film 63 functions as a mask material in the forming process of the contacts 29. Therefore, in the forming process of the contacts 29, the nucleation film 62 is exposed on the side surface and the bottom surface of each of the contact holes H29. Accordingly, tungsten formed at a low temperature is selectively formed in the contact holes H29 and is hardly formed in the trenches TR23p and TR23. Meanwhile, tungsten formed at a high temperature is formed in the trenches TR23p and TR23. Therefore, the contact holes H29 are filled with tungsten having a high level of coverage and the trenches TR23p and TR23 are filled with low-resistance tungsten. This enables the interconnection resistances of the lines 23p and the bit lines 23 to be decreased.

### Second embodiment

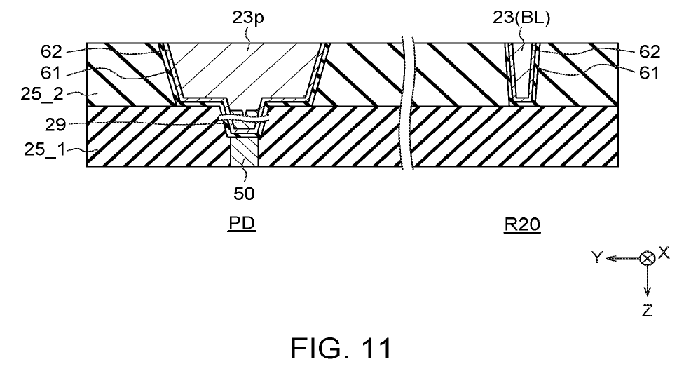

FIG. 11 is a sectional view illustrating a configuration example of a semiconductor device according to a second embodiment. In the second embodiment, the conductive film 63 is not left. The lines 23p are in direct contact with the nucleation film 62. The bit lines BL are also in direct contact with the nucleation film 62.

In the first embodiment, for example, tungsten (WN) including nitrogen that is relatively high in the resistance is used as the conductive film 63. In the second embodiment, the low-resistance second conductive material of the lines 23p and the bit lines 23 is provided instead of the conductive film 63 relatively high in the resistance. Accordingly, the resistances of the lines 23p and the bit lines 23 are decreased.

Other configurations of the second embodiment may be identical to those of the first embodiment. Therefore, the second embodiment can achieve effects similar to those of the first embodiment.

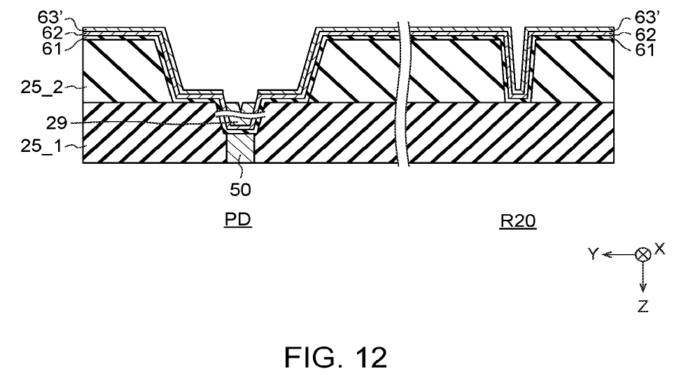

FIG. 12 is a sectional view illustrating one example of a manufacturing method of the semiconductor device according to the second embodiment. In the second embodiment, thermal treatment is performed after undergoing the processes explained with reference to FIGS. 6 to 9. When the conductive film 63 in FIG. 9 is, for example, tungsten (WN) including nitrogen, nitrogen is eliminated from the conductive film 63 by performing thermal treatment in a hydrogen environment to decrease the nitrogen concentration. Accordingly, the conductive film 63 is altered to tungsten (63’) having a lower nitrogen concentration. Furthermore, the particle diameter of tungsten in the conductive film 63 is increased by the thermal treatment. Such tungsten (63’) is lower in the resistance than tungsten having a high nitrogen concentration and has the same quality as that of tungsten formed at a high temperature, which is substantially the same tungsten as that constituting the lines 23p and the bit lines 23.

Subsequently, the semiconductor device 1 illustrated in FIG. 11 is completed after undergoing the processes explained with reference to FIG. 10.

As described above, in the second embodiment, the conductive film 63 used to selectively embed each of the contacts 29 in the associated contact hole H29 is thermally treated to be altered to tungsten low in the nitrogen concentration and having a low resistance. Accordingly, the conductive film 63 becomes tungsten having substantially the same quality as that constituting the lines 23p and the bit lines 23. As a result, the resistances of the lines 23p and the bit lines 23 can be further decreased.

### Third embodiment

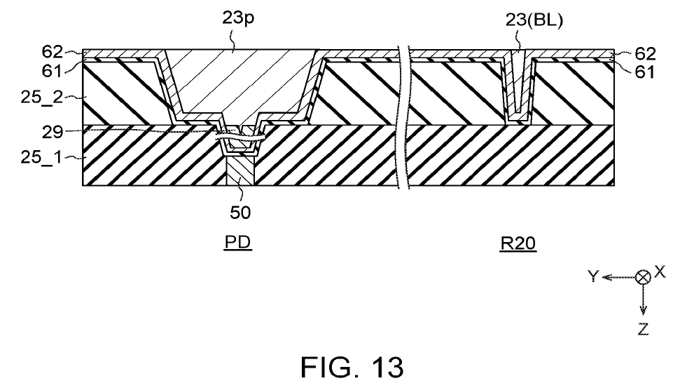

FIG. 13 is a sectional view illustrating a configuration example of a semiconductor device according to a third embodiment. In the third embodiment, the conductive film 63 is not left. The lines 23p are in direct contact with the nucleation film 62. The bit lines BL are also in direct contact with the nucleation film 62.

In the first embodiment, for example, tungsten (WN) including nitrogen relatively high in the resistance is used as the conductive film 63. In the third embodiment, the nucleation film 62 is provided instead of the conductive film 63 relatively high in the resistance. In the third embodiment, for example, tungsten including boron is used as the nucleation film 62. Tungsten including boron has a lower resistance than tungsten including nitrogen. Therefore, the resistances of the lines 23p and the bit lines 23 being in contact with the nucleation film 62 can be decreased.

The thickness of the nucleation film 62 provided on the side surface of each of the lines 23p and the bit lines 23 is larger than that of the nucleation film 62 provided between each of the contacts 29 and the associated line 50 and on the side surface of each of the contacts 29. This is because the conductive film 63 is altered to the nucleation film 62 (for example, tungsten including boron) in the manufacturing process.

Other configurations of the third embodiment may be identical to those of the first embodiment. Therefore, the third embodiment can achieve effects similar to those of the first embodiment.

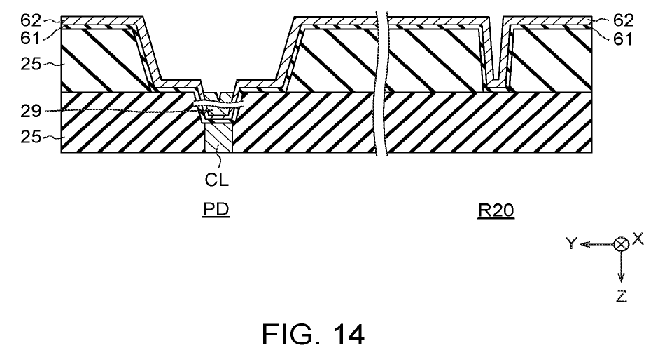

FIG. 14 is a sectional view illustrating one example of a manufacturing method of the semiconductor device according to the third embodiment. In the third embodiment, the processes explained with reference to FIGS. 6 to 9 are performed. At this time, the conductive film 63 in FIG. 8 is formed of, for example, the material gas (WF₆) with ammonia (NH₃) and diborane (B₂H₆) added as a reducing gas. Therefore, the conductive film 63 becomes, for example, tungsten (WBN) including nitrogen and boron. Subsequently, the contacts 29 are formed through the processes explained with reference to FIG. 9.

Next, thermal treatment is performed. When the conductive film 63 in FIG. 9 is tungsten (WBN) including nitrogen and boron, for example, nitrogen is eliminated from the conductive film 63 by the thermal treatment. Accordingly, the conductive film 63 is altered to tungsten including boron, which is low in the nitrogen concentration. Such tungsten is lower in the resistance than tungsten having a high nitrogen concentration and has substantially the same quality as that of tungsten including boron of the nucleation film 62. Therefore, in FIG. 14, the conductive film 63 is illustrated as the same film as the nucleation film 62. The conductive film 63 is not formed in the contact holes H29 and is formed in the trenches TR23p and TR23. Accordingly, the thickness of the nucleation film 62 is relatively small in the contact holes H29 and is relatively large in the trenches TR23p and TR23.

Subsequently, the semiconductor device 1 illustrated in FIG. 13 is completed after undergoing the processes explained with reference to FIG. 10.

As described above, in the third embodiment, the conductive film 63 used to selectively embed each of the contacts 29 in the associated contact hole H29 is thermally treated to be altered to tungsten including boron, which is low in the nitrogen concentration and having a low resistance. Accordingly, the conductive film 63 becomes a material substantially the same quality as tungsten including boron constituting the nucleation film 62. As a result, the resistances of the lines 23p and the bit lines 23 can be further decreased.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
first lines;
second lines respectively located on a side of a first direction of an associated one of the first lines;
first contacts electrically connecting between an associated one of the first lines and an associated one of the second lines, respectively; and
third lines respectively having a smaller width in a second direction intersecting with the first direction than those of the second lines and the first contacts and being located on a side of the second direction of an associated one of the second lines, wherein
the first contacts are constituted of a first conductive material, and
the second and third lines are constituted of a second conductive material having a lower resistance than that of the first conductive material.

2. The device of claim 1, wherein a concentration of impurities included in the second conductive material is lower than that of impurities included in the first conductive material.

3. The device of claim 2, wherein the impurity concentration is a fluorine concentration.

4. The device of claim 1, wherein the second conductive material has a particle diameter larger than that of the first conductive material.

5. The device of claim 1, further comprising a first conductive region located between one of the first contacts and an associated one of the first lines, on a side surface of one of the first contacts, on a side surface of one of the second lines, and on a side surface of one of the third lines.

6. The device of claim 2, further comprising a first conductive region located between one of the first contacts and an associated one of the first lines, on a side surface of one of the first contacts, on a side surface of one of the second lines, and on a side surface of one of the third lines.

7. The device of claim 3, further comprising a first conductive region located between one of the first contacts and an associated one of the first lines, on a side surface of one of the first contacts, on a side surface of one of the second lines, and on a side surface of one of the third lines.

8. The device of claim 4, further comprising a first conductive region located between one of the first contacts and an associated one of the first lines, on a side surface of one of the first contacts, on a side surface of one of the second lines, and on a side surface of one of the third lines.

9. The device of claim 5, wherein the first conductive region includes a tungsten film containing boron or a tungsten film containing silicon.

10. The device of claim 5, further comprising a second conductive region located between one of the second lines and the first conductive region and between one of the third lines and the first conductive region, and not located between one of the first contacts and the first conductive region.

11. The device of claim 10, wherein the second conductive region includes tungsten containing nitrogen.

12. The device of claim 10, wherein the second conductive region includes tungsten containing nitrogen and boron.

13. The device of claim 5, wherein the first conductive region located on the side surface of one of the second and third lines is thicker than the first conductive region located between one of the first contacts and an associated one of the first lines and on the side surface of one of the first contacts.

14. The device of claim 1, wherein the second lines are respectively in direct contact with an associated one of the first contacts.

15. A manufacturing method of a semiconductor device, the method comprising:
forming, on a first insulating film located on a side of a first direction of first lines, contact holes respectively reaching an associated one of the first lines, first trenches respectively located on the side of the first direction of an associated one of the contact holes to be communicated with the contact hole and having a larger width in a second direction intersecting with the first direction than that of the contact holes, and second trenches respectively located on a side of the second direction of an associated one of the first trenches and having a smaller width in the second direction than those of the contact holes and the first trenches;
forming a first conductive region in the first and second trenches and the contact holes;
selectively forming a second conductive region on the first conductive region on an inner wall of one of the first and second trenches;
forming first contacts by selectively embedding a first conductive material in the contact holes; and
forming one of second lines in the first direction of an associated one of the first contacts and forming one of third lines in the second direction of an associated one of the second lines by embedding a second conductive material on the second conductive region in the first and second trenches at a higher temperature than in a forming process of the first conductive material.

16. The method of claim 15, wherein the first conductive region is formed of tungsten fluoride (WF₆) with diborane (B₂H₆) or silane (SiH₄) added thereto.

17. The method of claim 15, wherein the second conductive region is formed of tungsten fluoride (WF₆) with ammonia (NH₃) added thereto.

18. The method of claim 17, wherein a nitrogen concentration of the second conductive region is decreased by performing thermal treatment on the second lines after formation thereof.

19. The method of claim 15, wherein the second conductive region is formed of tungsten fluoride (WF₆) with ammonia (NH₃) and diborane (B₂H₆) added thereto.

20. The method of claim 19, wherein a nitrogen concentration of the second conductive region is decreased by performing thermal treatment on the second lines after formation thereof.
